(19) United States
(12) Patent Application Publication
(10) Pub. No.: US 2015/0027760 A1
(43) Pub. Date: Jan. 29, 2015

(54) PRINTED CIRCUIT BOARD AND MANUFACTURING METHOD THEREOF

(71) Applicant: SAMSUNG ELECTRO-MECHANICS., LTD., Suwon (KR)

(72) Inventors: Seong Min CHO, Suwon (KR); Jung Youn PANG, Gunpo (KR); Eun Heay LEE, Suwon (KR); Seung Min KANG, Yeongi (KR)

(73) Assignee: SAMSUNG ELECTRO-MECHANICS., LTD., Suwon (KR)

(21) Appl. No.: 14/086,500

(22) Filed: Nov. 21, 2013

(30) Foreign Application Priority Data
Jul. 25, 2013 (KR) 10-2013-0088018

(51) Int. Cl. H05K 1/02; H05K 3/46; H05K 3/18

(52) U.S. Cl. CPC H05K 1/0271; H05K 3/181; H05K 3/4661
USPC 174/257; 174/261; 427/97.1; 205/183

(57) ABSTRACT

A printed circuit board includes an insulating layer; a metal pad formed on the insulating layer; a surface treatment layer formed on the metal pad; a solder layer formed on the surface treatment layer and the insulating layer; and an intermetallic compound layer formed between the solder layer and the surface treatment layer. Further, a printed circuit board may include an insulating layer; a metal seed layer formed on the insulating layer; a metal pad formed on the metal seed layer; a surface treatment layer formed on the metal pad and the metal seed layer; a solder layer formed on the surface treatment layer of the metal pad and the surface treatment layer of the metal seed layer; and an intermetallic compound layer formed between the solder layer and the surface treatment layer.

### CROSS-REFERENCE TO RELATED APPLICATIONS

This application claims the foreign priority benefit under 35 U.S.C. Section 119 of Korean Patent Application Serial No. 10-2013-0088018, filed Jul. 25, 2013, which is hereby incorporated by reference in its entirety into this application.

### BACKGROUND OF THE INVENTION

1. Field of the Invention

The present invention relates to a printed circuit board and a manufacturing method thereof, and more particularly, to a printed circuit board and a manufacturing method thereof that can improve reliability of solder joint according to internal/external shocks applied to the printed circuit board.

2. Description of the Related Art

In recent times, there are increasing demands for miniaturization for portability as well as various functions of electronic products. Due to this trend, various electronic components are mounted on substrates of the electronic products, and there is an increasing possibility that the electronic products are dropped or impacted when the electronic products are carried. Accordingly, high reliability of the electronic products is required. Particularly, in order to prevent a failure that the electronic component is separated from the substrate, high reliability is required for the solder interface that connects the electronic component and the substrate.

Typically, there are two methods of connecting various electronic components such as a die and a main board: a wire bonding method and a solder joint method. Among them, when using the solder joint method, reliability on the solder interface is a very important factor.

Meanwhile, according to high density of the electronic components, PCB surface treatment technologies become diverse. According to the demand of the times for PCB products that become thinner and dense, recently, the PCB surface treatment is changed from electro Ni/Au surface treatment to electroless surface treatment that can easily implement tailless in order to overcome the problems such as process simplification and noise free.

Particularly, when the surface treatment method is an electroless nickel (Ni)-gold (Au) (hereinafter, ENIG) plating layer or an electroless nickel (Ni)-palladium (Pd)-gold (Au) (hereinafter, ENEPIG) plating layer including Ni, an intermetallic compound (IMC) layer by diffusion of Ni and P atoms is formed between solder and a metal pad layer during solder joint for mounting and wire bonding of an electronic component after performing surface treatment on the metal pad layer.

The intermetallic compound layer can improve adhesion between the solder and the surface treatment plating layer due to its bonding characteristics but also has brittle characteristics.

Generally, in a printed circuit board having a typical structure, as shown in FIG. 1, solder 30 is bonded after performing surface treatment 20 such as ENIG or ENEPIG on a flat metal pad layer 10 formed on a base substrate. In this case, an intermetallic compound layer 40 is formed on the entire surface along the horizontal direction of the metal pad layer 10 and the surface treatment layer 20, that is, along the horizontal direction of a solder joint interface.

In the printed circuit board having the above structure, when external shocks or stress is applied, due to the intermetallic compound layer having brittle characteristics, a crack as shown in FIG. 2 spread to the entire surface along the horizontal direction of the solder joint interface, thus causing breaking or separation of the solder joint interface.

Therefore, there is a need to develop a printed circuit board and a manufacturing thereof that can improve reliability between an electronic component and circuit wiring mounted on the printed circuit board, particularly reliability of solder joint according to internal/external shocks applied to the printed circuit board.

### RELATED ART DOCUMENT

### Patent Document

Patent Document 1: Korean Patent Publication No. 10-1184875

### SUMMARY OF THE INVENTION

The present invention has been invented in order to overcome the above-described problems and it is, therefore, an object of the present invention to provide a printed circuit board and a manufacturing method thereof that can improve reliability by forming the shape of a soldering pad three-dimensionally to thereby control the shape of an intermetallic compound layer formed on a solder joint interface.

Further, it is another object of the present invention to provide a printed circuit board and a manufacturing method thereof that can improve adhesion between solder and a pad by forming the shape of the soldering pad three-dimensionally to thereby control the shape of an intermetallic compound layer formed on a solder joint interface.

In accordance with one aspect of the present invention to achieve the object, there is provided a printed circuit board including: an insulating layer; a metal pad formed on the insulating layer; a surface treatment layer formed on the metal pad; a solder layer formed on the surface treatment layer and the insulating layer; and an intermetallic compound layer formed between the solder layer and the surface treatment layer.

And in accordance with another aspect of the present invention to achieve the object, there is provided a printed circuit board including: an insulating layer; a metal seed layer formed on the insulating layer; a metal pad formed on the metal seed layer; a surface treatment layer formed on the metal pad and the metal seed layer; a solder layer formed on the surface treatment layer of the metal pad and the surface treatment layer of the metal seed layer; and an intermetallic compound layer formed between the solder layer and the surface treatment layer.

And in accordance with another aspect of the present invention to achieve the object, there is provided a manufacturing method of a printed circuit board, including: forming a metal pad on an insulating layer; forming a surface treatment layer on the metal pad; forming a solder layer on the surface treatment layer and the insulating layer; and forming an intermetallic compound layer between the solder layer and the surface treatment layer.

And in accordance with another aspect of the present invention to achieve the object, there is provided a manufacturing method of a printed circuit board, including: forming a metal seed layer on an insulating layer; forming a metal pad on the metal seed layer; forming a surface treatment layer on the metal pad and the metal seed layer; forming a solder layer on the surface treatment layer of the metal pad and the surface treatment layer of the metal seed layer; and forming an intermetallic compound layer between the solder layer and the surface treatment layer.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a cross-sectional view showing a printed circuit board having a typical structure;

FIG. 2 is a photograph showing a crack of an intermetallic compound layer formed in the printed circuit board of FIG. 1;

FIGS. 3A and 3B are a cross-sectional view and a plan view of a printed circuit board in accordance with a first embodiment of the present invention;

FIG. 4 is a flowchart for explaining a manufacturing method of the printed circuit board in accordance with the first embodiment of the present invention;

FIGS. 5A and 5B are a cross-sectional view and a plan view of the printed circuit board after performing a metal pad formation step in accordance with the first embodiment of the present invention;

FIG. 6A is a plan view after performing the metal pad formation step and a solder resist formation step in accordance with the first embodiment of the present invention;

FIG. 6B is a cross-sectional view of the printed circuit board after performing the metal pad formation step, the solder resist formation step, and a surface treatment layer formation step in accordance with the first embodiment of the present invention;

FIG. 7A is a cross-sectional view of the printed circuit board after performing the metal pad formation step, the solder resist formation step, the surface treatment layer formation step, a solder layer formation step, and an intermetallic compound layer formation step in accordance with the first embodiment of the present invention;

FIG. 7B is a plan view after performing the metal pad formation step, the solder resist formation step, and the surface treatment layer formation step in accordance with the first embodiment of the present invention;

FIGS. 8A and 8B are a cross-sectional view and a plan view of a printed circuit board in accordance with a second embodiment of the present invention;

FIG. 9 is a flowchart for explaining a manufacturing method of the printed circuit board in accordance with the second embodiment of the present invention;

FIGS. 10A and 10B are a cross-sectional view and a plan view of the printed circuit board after performing a metal seed layer formation step and a metal pad formation step in accordance with the second embodiment of the present invention;

FIG. 11A is a plan view after performing the metal seed layer formation step, the metal pad formation step, and a solder resist formation step in accordance with the second embodiment of the present invention;

FIG. 11B is a cross-sectional view of the printed circuit board after performing the metal seed layer formation step, the metal pad formation step, the solder resist formation step, and a surface treatment layer formation step in accordance with the second embodiment of the present invention;

FIG. 12A is a cross-sectional view of the printed circuit board after performing the metal seed layer formation step, the metal pad formation step, the solder resist formation step, the surface treatment layer formation step, a solder layer formation step, and an intermetallic compound layer formation step in accordance with the second embodiment of the present invention;

FIG. 12B is a plan view after performing the metal seed layer formation step, the metal pad formation step, the solder resist formation step, and the surface treatment layer formation step in accordance with the second embodiment of the present invention;

FIGS. 13A-13F are views showing simulation results of crack characteristics of the printed circuit board having a typical structure according to the time;

FIGS. 14A-14F are views showing simulation results of crack characteristics when the width d of the printed circuit board of the present invention in FIGS. 3A, 3B, 5A, 5B, 7A, 7B, 8A, 8B, 10A, 10B, 12A, and 12B is 10 μm;

FIGS. 15A-15F are views showing simulation results of crack characteristics when the width d of the printed circuit board of the present invention in FIGS. 3A, 3B, 5A, 5B, 7A, 7B, 8A, 8B, 10A, 10B, 12A, and 12B is 11 μm; and

FIGS. 16A-16F are views showing simulation results of crack characteristics when the width d of the printed circuit board of the present invention in FIGS. 3A, 3B, 5A, 5B, 7A, 7B, 8A, 8B, 10A, 10B, 12A and 12B is 15 μm.

### DETAILED DESCRIPTION OF THE PREFERABLE EMBODIMENTS

A matter regarding to an operational effect including a technical configuration for an object of a printed circuit board and a manufacturing method thereof in accordance with the present invention will be clearly appreciated through the following detailed description with reference to the accompanying drawings showing preferable embodiments of the present invention.

Further, in describing the present invention, descriptions of well-known techniques are omitted so as not to unnecessarily obscure the embodiments of the present invention. In the present specification, the terms “first,” “second,” and the like are used for distinguishing one element from another, and the elements are not limited by the above terms.

### First Embodiment

### Printed Circuit Board

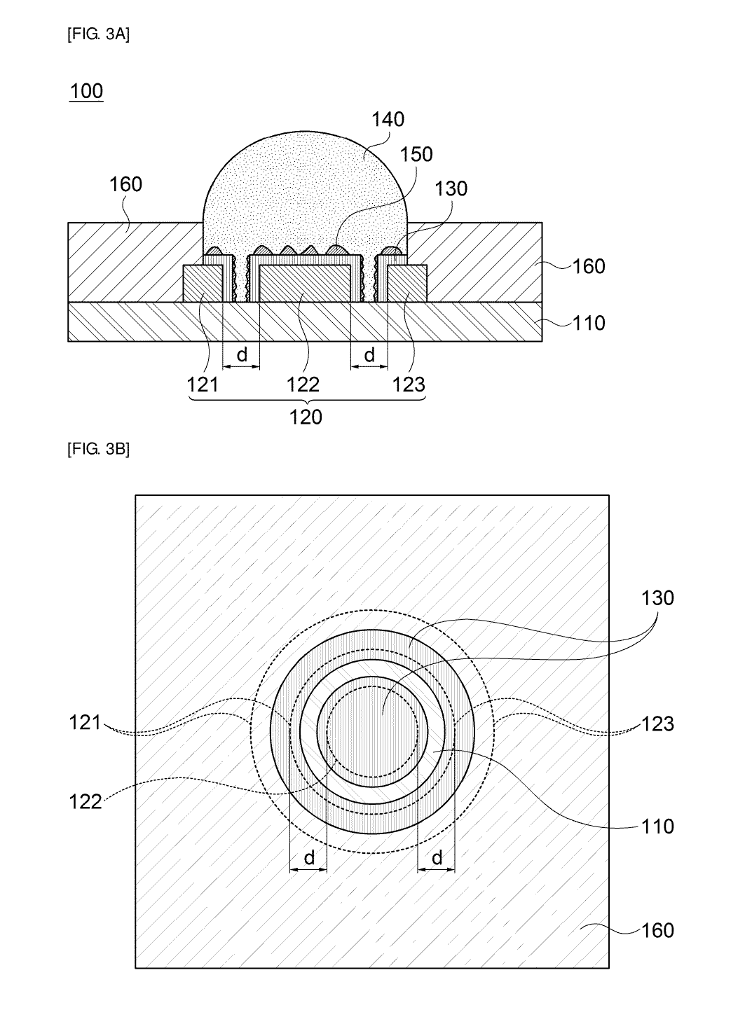

FIG. 3A shows a cross-sectional view of a printed circuit board in accordance with a first embodiment of the present invention. Further, FIG. 3B shows a plan view of the printed circuit board in accordance with the first embodiment of the present invention, particularly a plan view of the printed circuit board before a solder layer 140 and an intermetallic compound layer 150 in FIG. 3A are formed.

As shown in FIGS. 3A and 3B, a printed circuit board 100 according to the present embodiment may include an insulating layer 110, a metal pad 120, a surface treatment layer 130, a solder layer 140, and an intermetallic compound layer 150.

The insulating layer 110 may be made of a hard material that can support a build-up printed circuit board. For example, the insulating layer 110 may be made of an insulating material. Here, the insulating material may be a composite polymer resin. Otherwise, the insulating layer 110 may employ an Ajinomoto build-up film (ABF) to easily implement fine circuits or employ prepreg (PPG) to manufacture the printed circuit board thin.

However, the insulating layer 110 may be made of hard insulating materials including an epoxy resin or a modified epoxy resin, a bisphenol A resin, an epoxy-novolac resin, and an aramid-reinforced, glass fiber-reinforced, or paper-reinforced epoxy resin without being limited to the above composition.

The insulating layer 110 according to the present embodiment may be formed by employing the above-described prepreg or ABF.

The metal pad 120 is formed on the insulating layer 110. For example, the metal pad 120 may consist of an inner pad 122 and outer pads 121 and 123 as shown in FIGS. 3A and 3B.

At this time, the metal pad 120 may include a conductive metal and formed by a plating process and a patterning process. For example, the metal pad 120 may include at least one of gold, silver, nickel, aluminum, copper, and alloys thereof, but the metal pad 120 according to the present embodiment may include copper.

The surface treatment layer 130 may be formed on the metal pad 120 as shown in FIGS. 3A and 3B.

Here, the surface treatment layer 130 may be a metal surface treatment layer but is not limited thereto. For example, the metal surface treatment layer may include at least one of Cu, Ni, Pd, Au, Sn, and Ag.

Further, the metal surface treatment layer may be formed by an electroless plating method or an electroplating method. At this time, for example, the electroless plating method may include at least one of electroless nickel-electroless palladium-immersion gold (ENEPIG) that forms a plating layer consisting of an electroless nickel plating film, an electroless palladium plating film, and an electroless gold plating film and electroless nickel-immersion gold (ENIG) that forms a plating layer consisting of an electroless nickel plating film and an electroless gold plating film.

The solder layer 140 may be formed on the insulating layer 110 and the surface treatment layer 130 as shown in FIG. 3A. Although not shown in FIG. 3A, an electronic component such as a semiconductor chip may be mounted on the solder layer 140. Further, the solder layer 140 may perform electrical connection between the electronic component and the metal pad 120.

The intermetallic compound layer 150 may be formed between the surface treatment layer 130 and the solder layer 140 as shown in FIG. 3A.

That is, the intermetallic compound layer 150 may be formed from the surface treatment layer 130 that is formed by performing surface treatment on the metal pad 120 in a reflow process of bonding the solder layer 140 on the metal pad 120 for mounting the electronic component.

That is, the surface treatment layer 130 is formed by the surface treatment such as ENEPIG and ENIG before the reflow soldering process, and an electroless gold plating film included in the above surface treatment layer 130 is absorbed into the solder layer 140 and a main component Sn of the solder layer 140 and some copper (Cu) metal from the metal pad 120 are absorbed into nickel and gold of the above surface treatment layer 130 during the reflow soldering process to form a new layer, that is, the intermetallic compound layer 150 as shown in FIG. 3A.

Meanwhile, in the printed circuit board 100 according to the present embodiment, the solder layer 140 can be formed on the surface treatment layer 130 and the insulating layer 110 by forming the shape of the soldering pad three-dimensionally, thereby controlling the shape of the intermetallic compound layer 150 formed as above on a solder joint interface.

More specifically, the printed circuit board 100 according to the present embodiment, as shown in FIGS. 3A and 3B, for example, may be formed to have a width d between the inner pad 122 and the outer pads 121 and 123 of the metal pad 120 to form the shape of the soldering pad three-dimensionally.

Therefore, in the printed circuit board 100 of the present embodiment, the solder layer 140 can be formed on the surface treatment layer 130 of the metal pad 120 and the insulating layer 110 according to the above three-dimensional soldering pad, thereby controlling the shape of the intermetallic compound layer 150 formed on the solder joint interface.

In other words, the intermetallic compound layer 150, which is formed through the surface treatment layer 130 of the above three-dimensional soldering pad, can be controlled to have a three-dimensional shape with a step as shown in FIG. 3A.

Meanwhile, although FIG. 3B shows that the plane shape of both of the surface treatment layer 130 and the insulating layer 110 on which the solder layer 140 is formed is a ring shape and the ring-shaped surface treatment layer 130 and the ring-shaped insulating layer 110 are arranged alternately, the plane shape of both of the surface treatment layer 130 and the insulating layer 110 is not limited thereto. For example, the plane shape of one of the surface treatment layer 130 and the insulating layer 110 on which the solder layer 140 is formed may be a ring shape.

Further, it is preferred that the width d in FIGS. 3A and 3B, that is, the width d between the inner pad 122 and the outer pads 121 and 123 of the metal pad 120 is greater than 10 μm.

Meanwhile, the printed circuit board 100 according to the present embodiment may further include a solder resist 160 formed on the insulating layer 110 to embed a portion of the metal pad 120 therein as shown in FIGS. 3A and 3B.

The printed circuit board of the present embodiment configured as above, as described above, can control the intermetallic compound layer to have a three-dimensional shape with a step by forming the shape of the soldering pad three-dimensionally. Accordingly, even though external shock or stress is applied to the printed circuit board, a crack caused by the intermetallic compound layer are interrupted by the step, thus preventing the crack caused by the intermetallic compound layer from spreading to the entire surface along the horizontal direction of the solder joint interface.

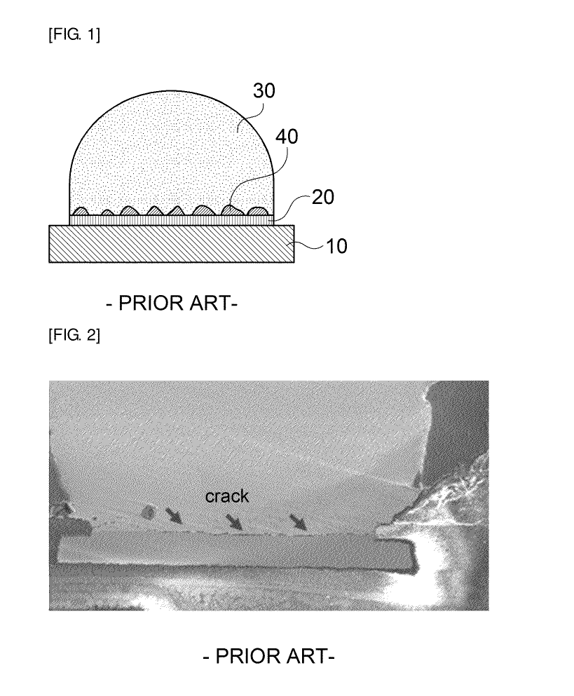

Therefore, the printed circuit board according to the present embodiment can improve the reliability of solder joint according to internal and external shocks applied to the printed circuit board, thus improving the reliability between the electronic component and the circuit wiring mounted on the printed circuit board compared to the printed circuit board having a typical structure shown in FIGS. 1 and 2.

In addition, the printed circuit board according to the present embodiment can form the intermetallic compound layer wider than the printed circuit board having a typical structure shown in FIGS. 1 and 2 by controlling the intermetallic compound layer to have a three-dimensional shape. Therefore, it is possible to increase the bonding area between the solder and the pad, thus improving the adhesion between the solder and the pad.

<Manufacturing Method of Printed Circuit Board>

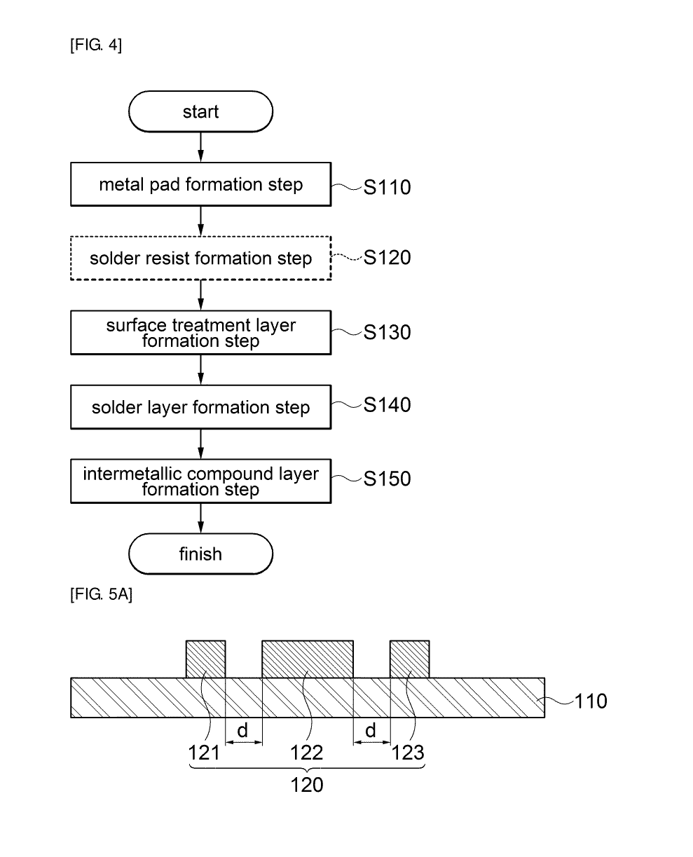

FIG. 4 is a flowchart for explaining a manufacturing method of the printed circuit board in accordance with the first embodiment of the present invention.

Referring to FIG. 4, first, the step S110 of forming a metal pad on an insulating layer may be performed.

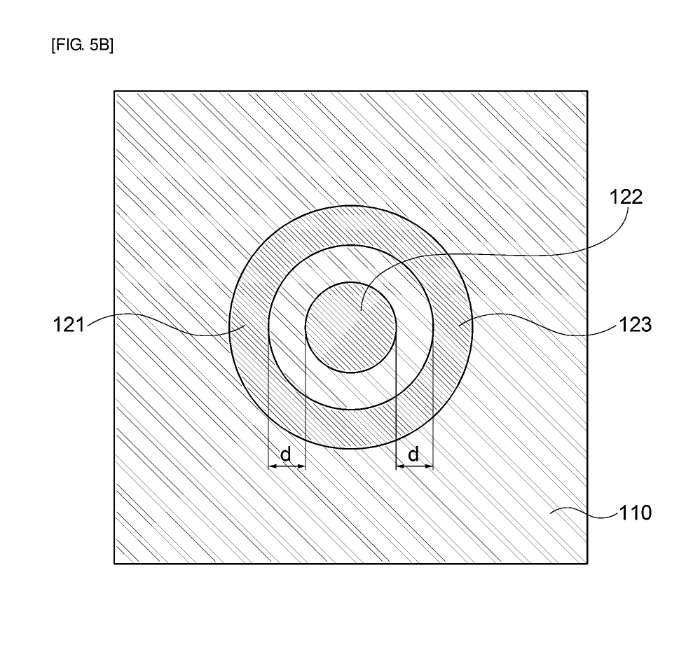

FIGS. 5A and 5B show a cross-sectional view and a plan view of the printed circuit board after performing the metal pad formation step S110.

The insulating layer 110 shown in FIGS. 5A and 5B may be made of a hard material that can support a build-up printed circuit board. For example, the insulating layer 110 may be made of an insulating material. Here, the insulating material may be a composite polymer resin. Otherwise, the insulating layer 110 may employ an Ajinomoto build-up film (ABF) to easily implement fine circuits or employ prepreg (PPG) to manufacture the printed circuit board thin.

However, the insulating layer 110 may be made of hard insulating materials including an epoxy resin or a modified epoxy resin, a bisphenol A resin, an epoxy-novolac resin, and an aramid-reinforced, glass fiber-reinforced, or paper-reinforced epoxy resin without being limited to the above composition.

The insulating layer 110 according to the present embodiment may be formed by employing the above-described prepreg or ABF.

Further, the metal pad 120 is formed on the insulating layer 110. For example, the metal pad 120 may consist of an inner pad 122 and outer pads 121 and 123 as shown in FIGS. 5A and 5B. Accordingly, the metal pad 120 can be formed to have a width d between the inner pad 122 and the outer pads 121 and 123. At this time, it is preferred that the width d is greater than 10 μm.

Further, the metal pad 120 may include a conductive metal. For example, the metal pad 120 may include at least one of gold, silver, nickel, aluminum, copper, and alloys thereof, but the metal pad 120 according to the present embodiment may include copper.

Further, the inner pad 122 and the outer pads 121 and 123 of the metal pad 120 may be formed as shown in FIGS. 5A and 5B as an example by forming a metal layer on the insulating layer 110 through typical plating and patterning processes and performing exposure, developing, and etching processes using a photoresist on the formed metal layer.

Back to FIG. 4 again, the step S130 of forming a surface treatment layer on the metal pad may be performed. Further, before the step S130 of forming the surface treatment layer, that is, between the step S110 of forming the metal pad and the step S130 of forming the surface treatment layer, the step S120 of forming a solder resist, which embeds a portion of the metal pad therein, on the insulating layer may be further included.

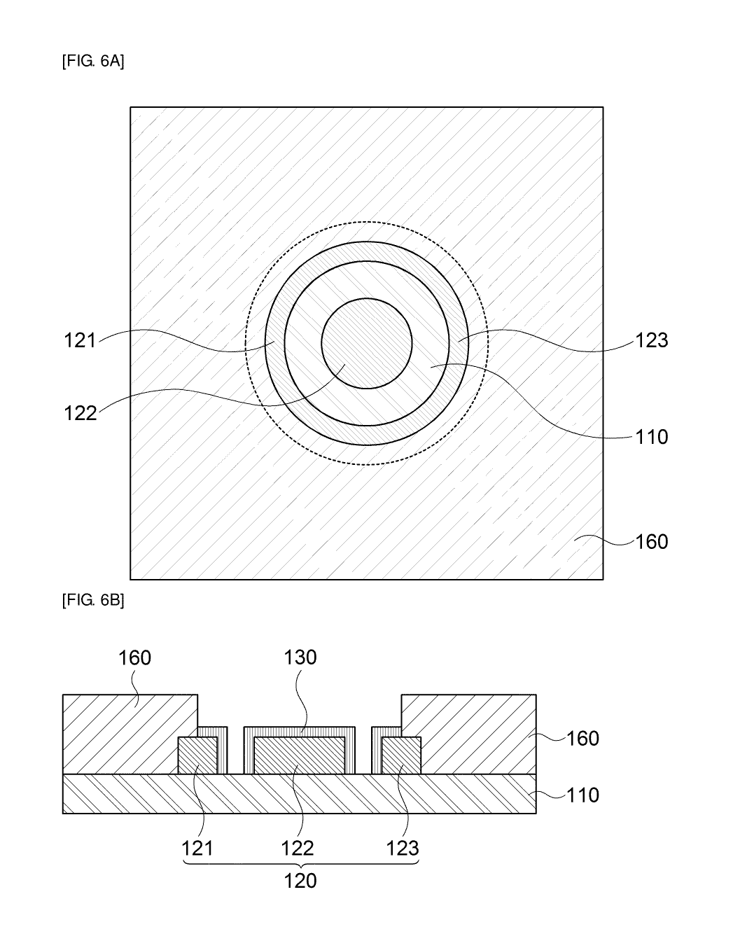

FIG. 6A shows a plan view after performing the metal pad formation step S110 and the solder resist formation step S120, and FIG. 6B shows a cross-sectional view of the printed circuit board after performing the metal pad formation step S110, the solder resist formation step S120, and the surface treatment layer formation step S130.

The solder resist 160 may be formed on the insulating layer 110 to embed the portion of the metal pad 120 therein as shown in FIGS. 6A and 6B.

Further, the surface treatment layer 130 may be formed on the metal pad 120 as shown in FIG. 6B.

Here, the surface treatment layer 130 may be a metal surface treatment layer but is not limited thereto. For example, the metal surface treatment layer may include at least one of Cu, Ni, Pd, Au, Sn, and Ag.

Further, the metal surface treatment layer may be formed by an electroless plating method or an electroplating method. At this time, for example, the electroless plating method may include at least one of electroless nickel-electroless palladium-immersion gold (ENEPIG) that forms a plating layer consisting of an electroless nickel plating film, an electroless palladium plating film, and an electroless gold plating film and electroless nickel-immersion gold (ENIG) that forms a plating layer consisting of an electroless nickel plating film and an electroless gold plating film.

Back to FIG. 4 again, the step S140 of forming a solder layer on the surface treatment layer and the insulating layer may be performed. Further, the step S150 of forming an intermetallic compound layer between the solder layer and the surface treatment layer may be performed.

FIG. 7A shows a cross-sectional view of the printed circuit board after performing the metal pad formation step S110, the solder resist formation step S120, the surface treatment layer formation step S130, the solder layer formation step S140, and the intermetallic compound layer formation step S150. Further, FIG. 7B shows a plan view after performing the metal pad formation step S110, the solder resist formation step S120, and the surface treatment layer formation step S130.

The solder layer 140 may be formed on the insulating layer 110 and the surface treatment layer 130 as shown in FIG. 7A. Although not shown in FIG. 7A, an electronic component such as a semiconductor chip may be mounted on the solder layer 140. Further, the solder layer 140 may perform electrical connection between the electronic component and the metal pad 120.

The intermetallic compound layer 150 may be formed between the surface treatment layer 130 and the solder layer 140 as shown in FIG. 7A.

That is, the intermetallic compound layer 150 may be formed from the surface treatment layer 130 that is formed by performing surface treatment on the metal pad 120 in a reflow process of bonding the solder layer 140 on the metal pad 120 for mounting the electronic component.

That is, the surface treatment layer 130 is formed by the surface treatment such as ENEPIG and ENIG before the reflow soldering process, and an electroless gold plating film included in the above surface treatment layer 130 is absorbed into the solder layer 140 and a main component Sn of the solder layer 140 and some copper (Cu) metal from the metal pad 120 are absorbed into nickel and gold of the above surface treatment layer 130 during the reflow soldering process to form a new layer, that is, the intermetallic compound layer 150 as shown in FIG. 7A.

In the printed circuit board formed according to the above manufacturing method, as shown in FIGS. 7A and 7B, the solder layer 140 can be formed on the surface treatment layer 130 and the insulating layer 110 by forming the shape of the soldering pad three-dimensionally, thereby controlling the shape of the intermetallic compound layer 150 formed as above on a solder joint interface.

More specifically, the printed circuit board formed according to the above manufacturing method, as shown in FIGS. 7A and 7B, for example, may be formed to have the width d between the inner pad 122 and the outer pads 121 and 123 of the metal pad 120 to form the shape of the soldering pad three-dimensionally.

Therefore, in the printed circuit board formed according to the above manufacturing method, the solder layer 140 can be formed on the surface treatment layer 130 of the metal pad 120 and the insulating layer 110 according to the three-dimensional soldering pad as shown in FIGS. 7A and 7B, thereby controlling the shape of the intermetallic compound layer 150 formed on the solder joint interface.

In other words, the intermetallic compound layer 150, which is formed through the surface treatment layer 130 of the above three-dimensional soldering pad, can be controlled to have a three-dimensional shape with a step as shown in FIG. 7A.

Meanwhile, although FIG. 7B shows that the plane shape of both of the surface treatment layer 130 and the insulating layer 110 on which the solder layer is formed in the step S140 of forming the solder layer is a ring shape and the ring-shaped surface treatment layer 130 and the ring-shaped insulating layer 110 are arranged alternately, the plane shape of the surface treatment layer 130 and the insulating layer 110 is not limited thereto. For example, the plane shape of one of the surface treatment layer 130 and the insulating layer 110 on which the solder layer 140 is formed may be a ring shape.

Further, it is preferred that the width d in FIGS. 7A and 7B, that is, the width d between the inner pad 122 and the outer pads 121 and 123 of the metal pad 120 is greater than 10 μm.

According to the manufacturing method of a printed circuit board of the present embodiment as above, it is possible to control the intermetallic compound layer to have a three-dimensional shape with a step by forming the shape of the soldering pad three-dimensionally. Accordingly, even though external shock or stress is applied to the printed circuit board, a crack caused by the intermetallic compound layer are interrupted by the step, thus preventing the crack caused by the intermetallic compound layer from spreading to the entire surface along the horizontal direction of the solder joint interface.

Therefore, according to the manufacturing method of a printed circuit board of the present embodiment, it is possible to improve the reliability of solder joint according to internal and external shocks applied to the printed circuit board, thus improving the reliability between the electronic component and the circuit wiring mounted on the printed circuit board compared to the printed circuit board having a typical structure shown in FIGS. 1 and 2.

In addition, according to the manufacturing method of a printed circuit board of the present embodiment, it is possible to form the intermetallic compound layer wider than the printed circuit board having a typical structure shown in FIGS. 1 and 2 by controlling the intermetallic compound layer to have a three-dimensional shape. Therefore, it is possible to increase the bonding area between the solder and the pad, thus improving the adhesion between the solder and the pad.

### Second Embodiment

### Printed Circuit Board

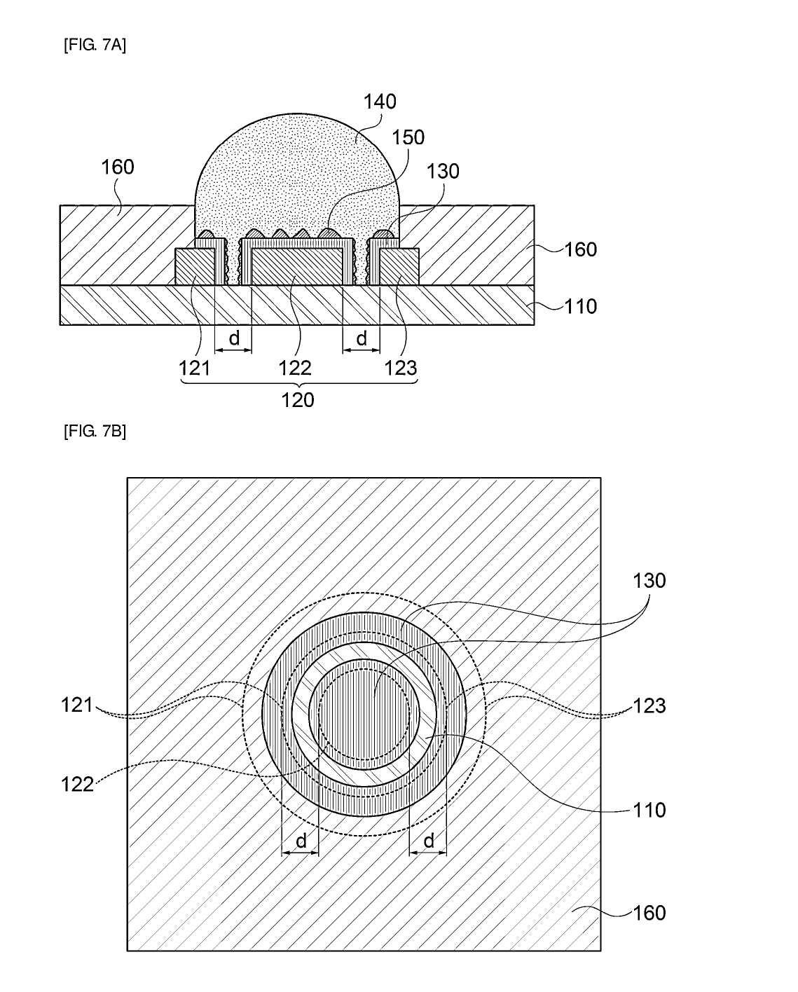

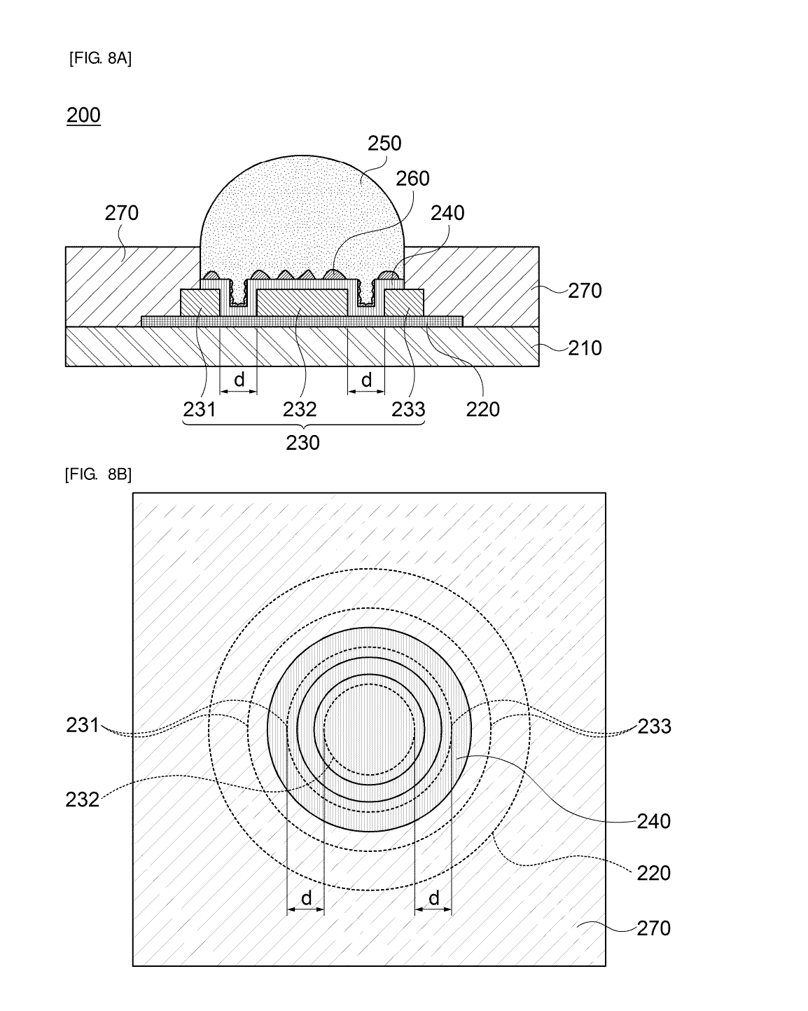

FIG. 8A shows a cross-sectional view of a printed circuit board in accordance with a second embodiment of the present invention. Further, FIG. 8B shows a plan view of the printed circuit board in accordance with the second embodiment of the present invention, particularly a plan view of the printed circuit board before a solder layer 250 and an intermetallic compound layer 260 in FIG. 8A are formed.

As shown in FIGS. 8A and 8B, a printed circuit board 200 according to the present embodiment may include an insulating layer 210, a metal seed layer 220, a metal pad 230, a surface treatment layer 240, a solder layer 250, and an intermetallic compound layer 260.

The insulating layer 210 may be made of a hard material that can support a build-up printed circuit board as in the first embodiment. For example, the insulating layer 210 may be made of an insulating material. Here, the insulating material may be a composite polymer resin. Otherwise, the insulating layer 210 may employ an Ajinomoto build-up film (ABF) to easily implement fine circuits or employ prepreg (PPG) to manufacture the printed circuit board thin.

However, the insulating layer 210 may be made of hard insulating materials including an epoxy resin or a modified epoxy resin, a bisphenol A resin, an epoxy-novolac resin, and an aramid-reinforced, glass fiber-reinforced, or paper-reinforced epoxy resin without being limited to the above composition.

The insulating layer 210 according to the present embodiment may be formed by employing the above-described prepreg or ABF as in the first embodiment.

The metal seed layer 220 may be formed on the insulating layer 210 as shown in FIG. 8A. At this time, the metal seed layer 220 may be made of base Cu but is not limited thereto. The metal seed layer 220 may be formed by electroless plating or electroplating.

The metal pad 230 is formed on the metal seed layer 220. For example, the metal pad 230 may consist of an inner pad 232 and outer pads 231 and 233 shown in FIGS. 8A and 8B.

At this time, the metal pad 230 may include a conductive metal and formed by a plating process and a patterning process as in the first embodiment. For example, the metal pad 230 may include at least one of gold, silver, nickel, aluminum, copper, and alloys thereof, but the metal pad 230 according to the present embodiment may include copper as in the first embodiment.

The surface treatment layer 240 may be formed on the metal pad 230 and the metal seed layer 220 as shown in FIGS. 8A and 8B.

Here, the surface treatment layer 240 may be a metal surface treatment layer as in the first embodiment but is not limited thereto. For example, the metal surface treatment layer may include at least one of Cu, Ni, Pd, Au, Sn, and Ag.

Further, the metal surface treatment layer may be formed by an electroless plating method or an electroplating method. At this time, for example, the electroless plating method may include at least one of electroless nickel-electroless palladium-immersion gold (ENEPIG) that forms a plating layer consisting of an electroless nickel plating film, an electroless palladium plating film, and an electroless gold plating film and electroless nickel-immersion gold (ENIG) that forms a plating layer consisting of an electroless nickel plating film and an electroless gold plating film.

The solder layer 250 may be formed on the surface treatment layer 240 of the metal pad 230 and the surface treatment layer 240 of the metal seed layer 220 as shown in FIG. 8a. Although not shown in FIG. 8A, an electronic component such as a semiconductor chip may be mounted on the solder layer 250 as in the first embodiment. Further, the solder layer 250 may perform electrical connection between the electronic component and the metal pad 230.

The intermetallic compound layer 260 may be formed between the surface treatment layer 240 and the solder layer 250 as shown in FIG. 8A.

That is, the intermetallic compound layer 260 may be formed from the surface treatment layer 240 that is formed by performing surface treatment on the metal seed layer 220 and the metal pad 230 in a reflow process of bonding the solder layer 250 on the metal pad 230 for mounting the electronic component.

That is, the surface treatment layer 240 is formed by the surface treatment such as ENEPIG and ENIG before the reflow soldering process, and an electroless gold plating film included in the above surface treatment layer 240 is absorbed into the solder layer 250 and a main component Sn of the solder layer 250 and some copper (Cu) metal from the metal pad 230 and the metal seed layer 220 are absorbed into nickel and gold of the above surface treatment layer 240 during the reflow soldering process to form a new layer, that is, the intermetallic compound layer 260 as shown in FIG. 8A.

Meanwhile, the printed circuit board 200 according to the present embodiment can form the solder layer 250 on the surface treatment layer 240 of the metal pad 230 and the surface treatment layer 240 of the metal seed layer 220 by forming the shape of the soldering pad three-dimensionally as shown in FIGS. 8A and 8B, thereby controlling the shape of the intermetallic compound layer 260 formed as above on a solder joint interface.

More specifically, as shown in FIGS. 8A and 8B, for example, the printed circuit board 200 according to the present embodiment may be formed to have a width d between the inner pad 232 and the outer pads 231 and 233 of the metal pad 230 to form the shape of the soldering pad three-dimensionally.

Therefore, in the printed circuit board 200 of the present embodiment, the solder layer 250 can be formed on the surface treatment layer 240 of the metal pad 230 and the surface treatment layer 240 of the metal seed layer 220 according to the above three-dimensional soldering pad, thereby controlling the shape of the intermetallic compound layer 260 formed on the solder joint interface.

In other words, the intermetallic compound layer 260, which is formed through the surface treatment layer 240 of the above three-dimensional soldering pad, can be controlled to have a three-dimensional shape with a step as shown in FIG. 8A.

At this time, the intermetallic compound layer 260 of the present embodiment may be formed on the surface treatment layer of the metal seed layer 220 as well as on the surface treatment layer of the metal pad 230 as shown in FIG. 8A, unlike the first embodiment.

Therefore, in the printed circuit board 200 of the present embodiment, the intermetallic compound layer can be formed wider than that of the printed circuit board of the first embodiment. Thus, it is possible to improve the adhesion between the solder and the metal pad layer compared to the printed circuit board of the first embodiment.

Meanwhile, although FIG. 8A shows that the plane shape of both of the surface treatment layer 240 of the metal pad 230 and the surface treatment layer 240 of the metal seed layer 220 on which the solder layer 240 is formed is a ring shape and the ring-shaped surface treatment layer 240 of the metal pad 230 and the ring-shaped surface treatment layer 240 of the metal seed layer 220 are arranged alternately, the plane shape the surface treatment layer 240 of the metal pad 230 and the surface treatment layer 240 of the metal seed layer 220 is not limited thereto. For example, the plane shape of one of the surface treatment layer 240 of the metal pad 230 and the surface treatment layer 240 of the metal seed layer 220 on which the solder layer 240 is formed may be a ring shape.

Further, it is preferred that the width d in FIGS. 8A and 8B, that is, the width d between the inner pad 232 and the outer pads 231 and 233 of the metal pad 230 is greater than 10 μm.

Meanwhile, the printed circuit board 200 according to the present embodiment may further include a solder resist 270 formed on the insulating layer 210 to embed portions of the metal pad 230 and the metal seed layer 220 therein as shown in FIGS. 8A and 8B.

The printed circuit board of the present embodiment configured as above, like the first embodiment, can control the intermetallic compound layer to have a three-dimensional shape with a step by forming the shape of the soldering pad three-dimensionally. Accordingly, even though external shock or stress is applied to the printed circuit board, a crack caused by the intermetallic compound layer are interrupted by the step, thus preventing the crack caused by the intermetallic compound layer from spreading to the entire surface along the horizontal direction of the solder joint interface.

Therefore, the printed circuit board according to the present embodiment can improve the reliability of solder joint according to internal and external shocks applied to the printed circuit board, thus improving the reliability between the electronic component and the circuit wiring mounted on the printed circuit board compared to the printed circuit board having a typical structure shown in FIGS. 1 and 2.

In addition, the printed circuit board according to the present embodiment can form the intermetallic compound layer wider than the printed circuit board having a typical structure shown in FIGS. 1 and 2 by controlling the intermetallic compound layer to have a three-dimensional shape as in the first embodiment. Therefore, it is possible to increase the bonding area between the solder and the pad, thus improving the adhesion between the solder and the pad.

<Manufacturing Method of Printed Circuit Board>

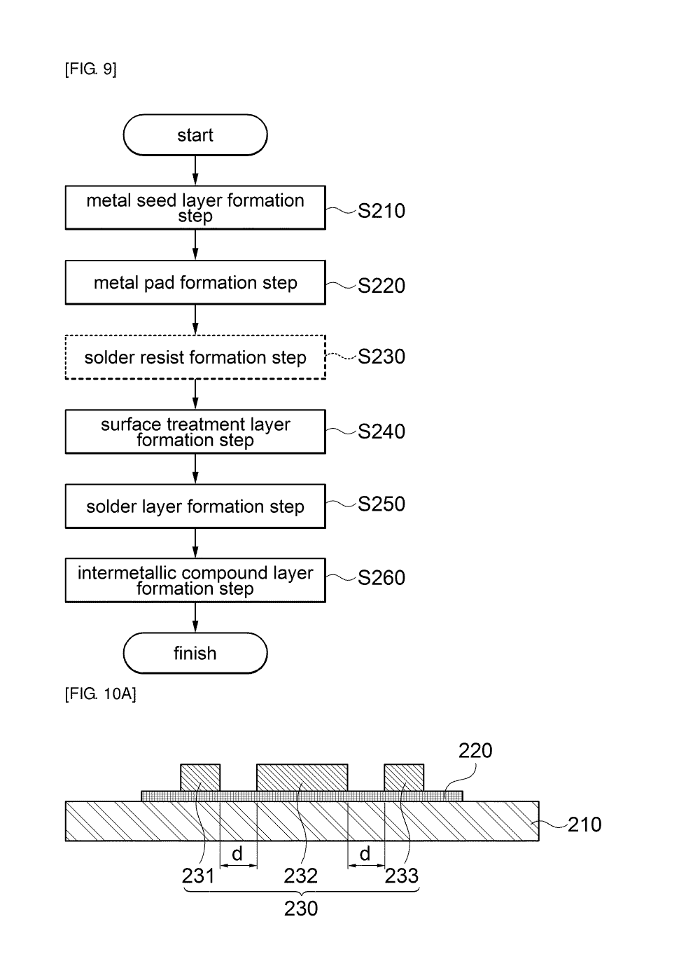

FIG. 9 is a flowchart for explaining a manufacturing method of the printed circuit board in accordance with the second embodiment of the present invention.

Referring to FIG. 9, first, the step S210 of forming a metal seed layer on an insulating layer may be performed. Further, the step S220 of forming a metal pad on the formed metal seed layer may be performed.

FIGS. 10A and 10B show a cross-sectional view and a plan view of the printed circuit board after performing the metal seed layer formation step S210 and the metal pad formation step S220.

The insulating layer 210 shown in FIGS. 10A and 10B may be made of a hard material that can support a build-up printed circuit board as in the first embodiment. For example, the insulating layer 210 may be made of an insulating material. Here, the insulating material may be a composite polymer resin. Otherwise, the insulating layer 210 may employ an Ajinomoto build-up film (ABF) to easily implement fine circuits or employ prepreg (PPG) to manufacture the printed circuit board thin.

However, the insulating layer 210 may be made of hard insulating materials including an epoxy resin or a modified epoxy resin; a bisphenol A resin; an epoxy-novolac resin; and an aramid-reinforced, glass fiber-reinforced, or paper-reinforced epoxy resin without being limited to the above composition.

The insulating layer 210 according to the present embodiment may be formed by employing the above-described prepreg or ABF.

Further, the metal seed layer 220 may be formed on the insulating layer 210. At this time, the metal seed layer 220 may be made of base Cu but is not limited thereto. The metal seed layer 220 may be formed by electroless plating or electroplating.

Further, the metal pad 230 is formed on the metal seed layer 220. As shown in FIGS. 10A and 10B, for example, the metal pad 230 may consist of an inner pad 232 and outer pads 231 and 233. Accordingly, the metal pad 230 can be formed to have a width d between the inner pad 232 and the outer pads 231 and 233. At this time, it is preferred that the width d is greater than 10 μm.

Further, the metal pad 230 may include a conductive metal as in the first embodiment. For example, the metal pad 230 may include at least one of gold, silver, nickel, aluminum, copper, and alloys thereof, but the metal pad 230 according to the present embodiment may include copper as in the first embodiment.

Further, the inner pad 232 and the outer pads 231 and 233 of the metal pad 230 may be formed as shown in FIGS. 10A and 10B as an example by forming a metal layer on the metal seed layer 220 through typical plating and patterning processes and performing exposure, developing, and etching processes using a photoresist on the formed metal layer.

Back to FIG. 4 again, the step S240 of forming a surface treatment layer on the metal pad and the metal seed layer may be performed. Further, before the step S240 of forming the surface treatment layer, that is, between the step S220 of forming the metal pad and the step S240 of forming the surface treatment layer, the step S230 of forming a solder resist, which embeds portions of the metal pad and the metal seed layer therein, on the insulating layer may be further included.

FIG. 11A shows a plan view after performing the metal seed layer formation step S210, the metal pad formation step S220, and the solder resist formation step S230, and FIG. 11B shows a cross-sectional view of the printed circuit board after performing the metal seed layer formation step S210, the metal pad formation step S220, the solder resist formation step S230, and the surface treatment layer formation step S240.

The solder resist 270 may be formed on the insulating layer 210 to embed the portions of the metal pad 230 and the metal seed layer 220 therein as shown in FIGS. 11A and 11B.

Further, the surface treatment layer 240 may be formed on the metal pad 230 and the metal seed layer 220 as shown in FIG. 11B.

Here, the surface treatment layer 240 may be a metal surface treatment layer but is not limited thereto. For example, the metal surface treatment layer may include at least one of Cu, Ni, Pd, Au, Sn, and Ag.

Further, the metal surface treatment layer may be formed by an electroless plating method or an electroplating method. At this time, for example, the electroless plating method may include at least one of electroless nickel-electroless palladium-immersion gold (ENEPIG) that forms a plating layer consisting of an electroless nickel plating film, an electroless palladium plating film, and an electroless gold plating film and electroless nickel-immersion gold (ENIG) that forms a plating layer consisting of an electroless nickel plating film and an electroless gold plating film.

Back to FIG. 9 again, the step S250 of forming a solder layer on the surface treatment layer of the metal pad and the surface treatment layer of the metal seed layer may be performed. Further, the step S260 of forming an intermetallic compound layer between the solder layer and the surface treatment layer may be performed.

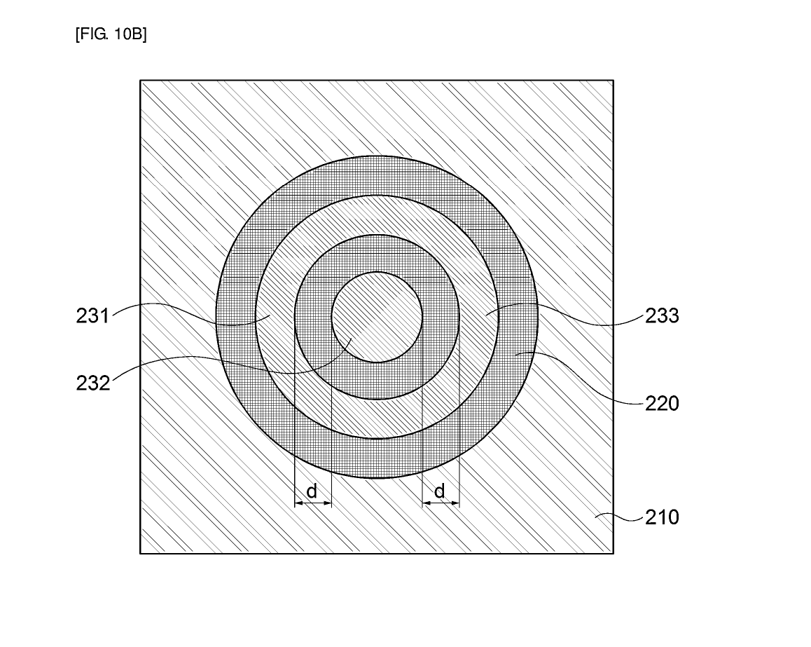

FIG. 12A shows a cross-sectional view of the printed circuit board after performing the metal seed layer formation step S210, the metal pad formation step S220, the solder resist formation step S230, the surface treatment layer formation step S240, the solder layer formation step S250, and the intermetallic compound layer formation step S260. Further, FIG. 12B shows a plan view of the printed circuit board after performing the metal seed layer formation step S210, the metal pad formation step S220, and the solder resist formation step S230.

The solder layer 250 may be formed on the surface treatment layer 240 of the metal pad 230 and the surface treatment layer 240 of the metal seed layer 220 as shown in FIG. 12A. Although not shown in FIG. 12A, an electronic component such as a semiconductor chip may be mounted on the solder layer 250. Further, the solder layer 250 may perform electrical connection between the electronic component and the metal pad 230.

The intermetallic compound layer 260 may be formed between the surface treatment layer 240 and the solder layer 250 as shown in FIG. 12A.

That is, the intermetallic compound layer 260 may be formed from the surface treatment layer 240 that is formed by performing surface treatment on the metal pad 230 and the metal seed layer 220 in a reflow process of bonding the solder layer 250 on the metal pad 230 for mounting the electronic component.

That is, the surface treatment layer 240 is formed by the surface treatment such as ENEPIG and ENIG before the reflow soldering process, and an electroless gold plating film included in the above surface treatment layer 240 is absorbed into the solder layer 250 and a main component Sn of the solder layer 250 and some copper (Cu) metal from the metal seed layer 220 and the metal pad 230 are absorbed into nickel and gold of the above surface treatment layer 240 during the reflow soldering process to form a new layer, that is, the intermetallic compound layer 260 as shown in FIG. 12A.

The printed circuit board formed according to the above manufacturing method, as shown in FIGS. 12A and 12B, can form the solder layer 250 on the surface treatment layer 240 of the metal pad 230 and the surface treatment layer 240 of the metal seed layer 220 by forming the shape of the soldering pad three-dimensionally, thereby controlling the shape of the intermetallic compound layer 260 formed as above on a solder joint interface.

More specifically, the printed circuit board formed according to the above manufacturing method, as shown in FIGS. 12A and 12B, for example, may be formed to have the width d between the inner pad 232 and the outer pads 231 and 233 of the metal pad 230 to form the shape of the soldering pad three-dimensionally.

Therefore, in the printed circuit board formed according to the above manufacturing method, the solder layer 250 can be formed on the surface treatment layer 240 of the metal pad 230 and the surface treatment layer 240 of the metal seed layer 220 according to the three-dimensional soldering pad as shown in FIGS. 12A and 12B, thereby controlling the shape of the intermetallic compound layer 260 formed on the solder joint interface.

In other words, the intermetallic compound layer 260, which is formed through the surface treatment layer 240 of the above three-dimensional soldering pad, can be controlled to have a three-dimensional shape with a step as shown in FIG. 12A.

At this time, the intermetallic compound layer 260 of the present embodiment is formed on the surface treatment layer of the metal seed layer 220 as well as on the surface treatment layer of the metal pad 230 as shown in FIG. 12A, unlike the first embodiment.

Therefore, in the printed circuit board of the present embodiment, the intermetallic compound layer can be formed wider than that of the printed circuit board of the first embodiment. Thus, it is possible to improve the adhesion between the solder and the metal pad layer compared to the printed circuit board of the first embodiment.

Meanwhile, although FIG. 12B shows that the plane shape of both of the surface treatment layer 240 of the metal pad 230 and the surface treatment layer 240 of the metal seed layer 220 on which the solder layer is formed in the step S250 of forming the solder layer is a ring shape and the ring-shaped surface treatment layer 240 of the metal pad 230 and the ring-shaped surface treatment layer 240 of the metal seed layer 220 are arranged alternately, the plane shape of the surface treatment layer 240 of the metal pad 230 and the surface treatment layer 240 of the metal seed layer 220 is not limited thereto. For example, the plane shape of one of the surface treatment layer 240 of the metal pad 230 and the surface treatment layer 240 of the metal seed layer 220 on which the solder layer 250 is formed may be a ring shape.

Further, it is preferred that the width d in FIGS. 12A and 12B, that is, the width d between the inner pad 232 and the outer pads 231 and 233 of the metal pad 230 is greater than 10 μm.

According to the manufacturing method of a printed circuit board of the present embodiment as above, it is possible to control the intermetallic compound layer to have a three-dimensional shape with a step by forming the shape of the soldering pad three-dimensionally. Accordingly, even though external shock or stress is applied to the printed circuit board, a crack caused by the intermetallic compound layer are interrupted by the step, thus preventing the crack caused by the intermetallic compound layer from spreading to the entire surface along the horizontal direction of the solder joint interface.

Therefore, according to the manufacturing method of a printed circuit board of the present embodiment, it is possible to improve the reliability of solder joint according to internal and external shocks applied to the printed circuit board, thus improving the reliability between the electronic component and the circuit wiring mounted on the printed circuit board compared to the printed circuit board having a typical structure shown in FIGS. 1 and 2.

In addition, according to the manufacturing method of a printed circuit board of the present embodiment, it is possible to form the intermetallic compound layer wider than the printed circuit board having a typical structure shown in FIGS. 1 and 2 by controlling the intermetallic compound layer to have a three-dimensional shape. Therefore, it is possible to increase the bonding area between the solder and the pad, thus improving the adhesion between the solder and the pad.

Crack Characteristics According to Intermetallic Compound Layer of the Present Embodiment

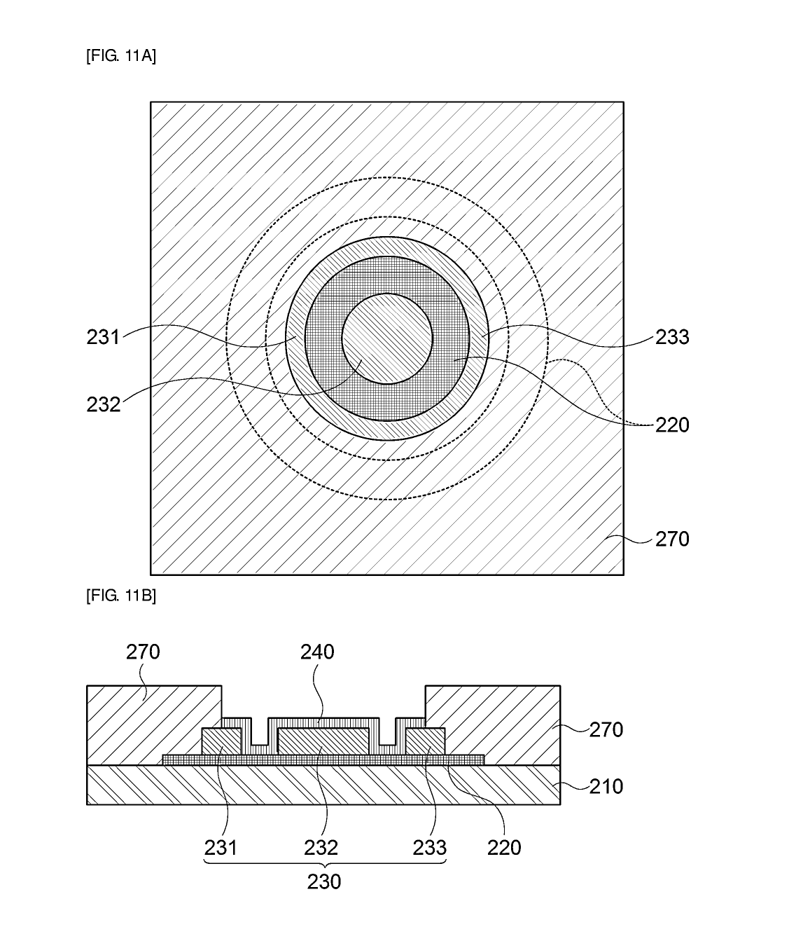

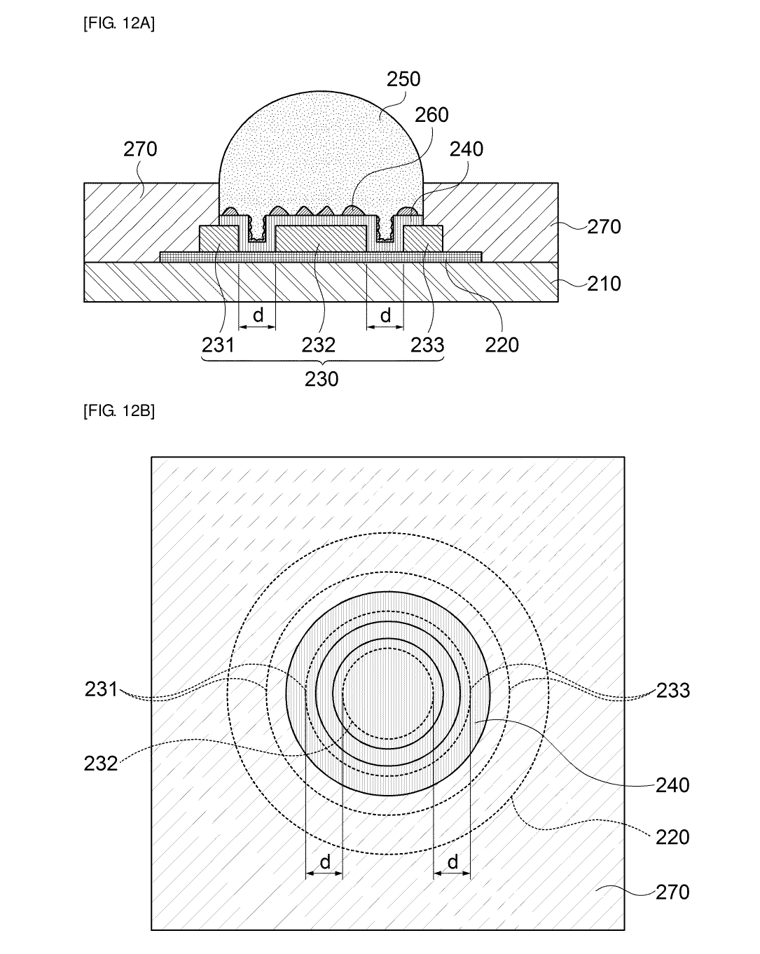

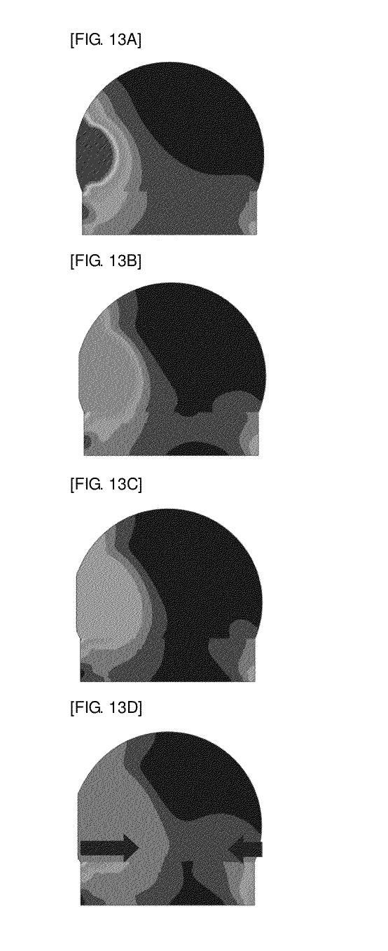

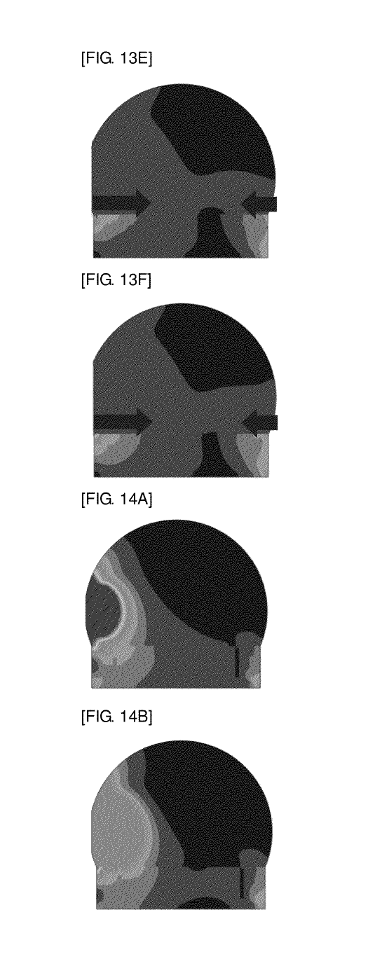

The printed circuit board according to the present invention configured as above is manufactured by the above-described manufacturing method, and crack characteristics when predetermined stress is applied to the printed circuit board having a typical structure, that is, the printed circuit board (printed circuit board shown in FIGS. 1 and 2) in which the intermetallic compound layer is formed on the entire surface along the horizontal direction of the solder joint interface and the printed circuit board according to the present invention are simulated as in FIGS. 13A through 16F shown below.

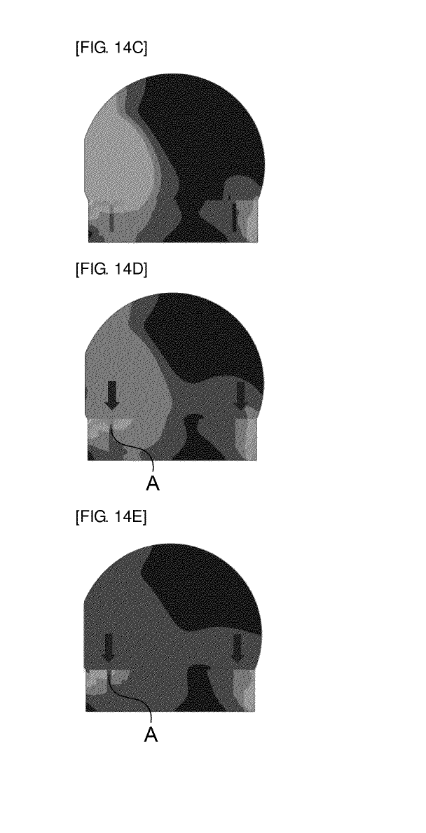

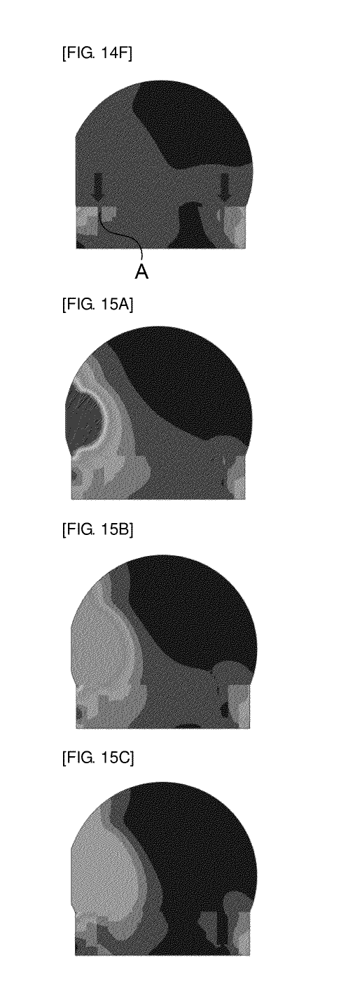

FIGS. 13A-13F are views showing simulation results of the crack characteristics of the printed circuit board having a typical structure according to the time, and FIGS. 14A through 16F are views showing simulation results of the crack characteristics of the printed circuit board in accordance with the first and second embodiments of the present invention according to the time.

In the printed circuit board having a typical structure, that is, the printed circuit board (shown in FIGS. 1 and 2) in which the intermetallic compound layer is formed on the entire surface along the horizontal direction of the solder joint interface, as shown in FIGS. 13A to 13F, a crack due to the intermetallic compound layer are not interrupted even though stress is applied (FIG. 13A) so that the stress is transmitted in the horizontal direction along the intermetallic compound layer with the passage of time (FIGS. 13D to 13F).

On the other hand, in the printed circuit board according to the first and second embodiments of the present invention, that is, the printed circuit board in which the shape of the soldering pad is formed three-dimensionally and thus the shape of the intermetallic compound layer is formed three-dimensionally, as shown in FIGS. 14 to 16(a) to (f), an interrupted portion A of the crack due to the intermetallic compound layer occurs after some time when stress is applied (FIGS. 14A to 16A) so that the transmission of the stress to the solder joint interface is blocked (FIGS. 14A to 16D to 16E).

Through the above simulation results of FIGS. 13A through 16F, it can be understood that the printed circuit board of the first and second embodiments has crack interruption characteristics due to the three-dimensional shape of the intermetallic compound layer compared to the printed circuit board having a typical structure, thus blocking the transmission of the stress to the solder joint interface.

That is, in the printed circuit board according to the present invention, the crack due to the intermetallic compound layer are interrupted even when external shock or stress is applied to the printed circuit board by forming the shape of the soldering pad three-dimensionally and thus forming (control) the shape of the intermetallic compound layer three-dimensionally, thereby improving the reliability of solder joint according to internal/external shocks applied to the printed circuit board compared to the printed circuit board having a typical structure. Therefore, the printed circuit board according to the present invention also can improve the reliability between the electronic component and the circuit wiring mounted on the printed circuit board.

Meanwhile, in the printed circuit board of the present invention having the above-described technical characteristics of the first and second embodiments, in order to implement the improved crack interruption characteristics, it is preferred to increase the width (d in FIGS. 3A-3B, 5A-5B, 7A-7B, 8A-8B, 10A-10B, 12A-12B) between the inner metal pad and the outer metal pad, that is, the width between the metal pad and the adjacent another metal pad to greater than 10 μm. This can be applied to both of the above-described printed circuit boards of the first embodiment and the second embodiment.

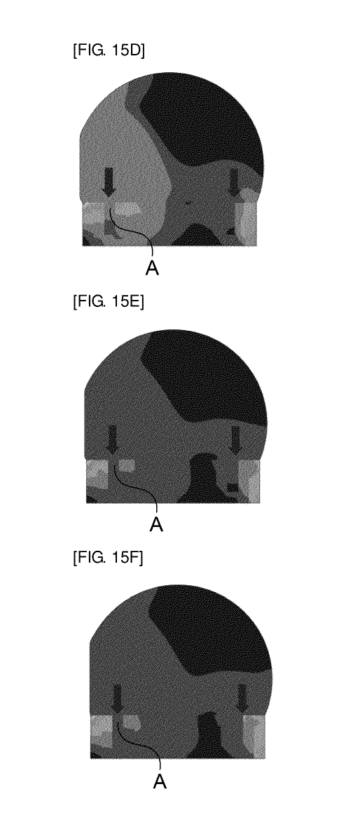

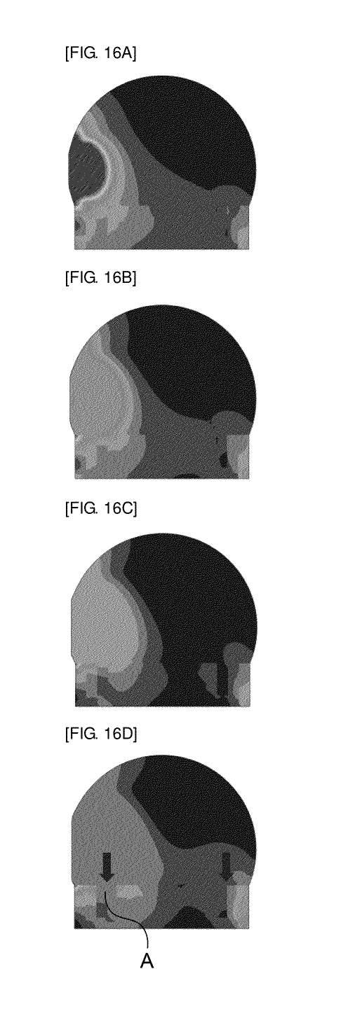

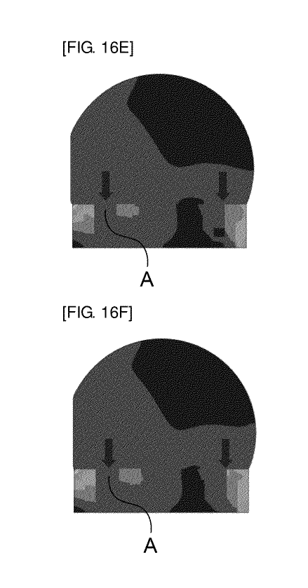

FIGS. 14A to 16F show the simulation results of the crack characteristics of the printed circuit board of the present invention according to the width d, wherein FIG. 14 shows the case in which the width d is 10 μm, FIG. 15 shows the case in which the width d is 11 μm, and FIG. 16 shows the case in which the width d is 15 μm.

As shown in FIGS. 14A to 16F, in the printed circuit board of the present invention, the case in which the width d is greater than 10 μm (11 μm, 15 μm) exhibits much better crack interruption characteristics in the intermetallic compound layer than the case in which the width d is 10 μm.

Therefore, even considering the above the simulation results, for the better crack interruption characteristics, it is preferred to increase the width (d in FIGS. 3A-3B, 5A-5B, 7A-7B, 8A-8B, 10A-10B, 12A-12B) between the inner metal pad and the outer metal pad, that is, the width between the metal pad and the adjacent another metal pad to greater than 10 μm.

As described above, the printed circuit board and the manufacturing method thereof according to the present invention can improve the reliability of solder joint according to internal/external shocks applied to the printed circuit board by forming the shape of the soldering pad three-dimensionally and thus controlling the shape of the intermetallic compound layer formed on the solder joint interface, thereby improving the reliability between the electronic component and the metal pad layer.

Further, the printed circuit board and the manufacturing method thereof according to the present invention can increase the bonding area between the solder and the pad by forming the shape of the soldering pad three-dimensionally and thus controlling the shape of the intermetallic compound layer formed on the solder joint interface, thereby improving the adhesion between the solder and the pad.

Reference in the specification to “an embodiment” of the present principles, as well as other variations thereof, means that a particular feature, structure, characteristic, and so forth described in connection with the embodiment is included in at least one embodiment of the present principles. Thus, the appearances of the phrase “in an embodiment”, as well as any other variations, appearing in various places throughout the specification are not necessarily all referring to the same embodiment.

While operations are depicted in the drawings of the present invention, this should not be understood as requiring that such operations be performed in the particular order shown or that all illustrated operations be performed to achieve desirable results. In certain circumstances, multitasking and parallel processing may be advantageous.

In the specification, “at least one of” in the case of “at least one of A and B” is intended to encompass the selection of the first listed option (A) only, or the selection of the second listed option (B) only, or the selection of both options (A and B). As a further example, the case of “at least one of A, B, and C” is intended to encompass the selection of the first listed option (A) only, or the selection of the second listed option (B) only, or the selection of the third listed option (C) only, or the selection of the first and second listed options (A and B) only, or the selection of the second and third listed options (B and C) only, or the selection of all three options (A, B, and C). This can be extended, as readily apparent by those skilled in the related arts, for as many items listed.

So far the preferable embodiments of the present invention have been described. All the embodiments and conditional examples disclosed through the specification are intended to help those skilled in the art to understand the principles and concepts of the present invention, and it will be appreciated by those skilled in the art that the present invention can be implemented in a modified form without departing from the essential characteristics of the present invention. Therefore, the embodiments should be considered in descriptive sense and not for purpose of limitation. The scope of the present invention is defined by the appended claims rather than the foregoing description, and all differences within the scope will be construed as being included in the present invention.

What is claimed is:

1. A printed circuit board comprising:
an insulating layer;
a metal pad formed on the insulating layer;
a surface treatment layer formed on the metal pad;
a solder layer formed on the surface treatment layer and the insulating layer; and
an intermetallic compound layer formed between the solder layer and the surface treatment layer.

2. The printed circuit board according to claim 1, wherein the plane shape of one or both of the surface treatment layer and the insulating layer on which the solder layer is formed is a ring shape.

3. The printed circuit board according to claim 2, wherein the ring-shaped surface treatment layer and the ring-shaped insulating layer are arranged alternately.

4. The printed circuit board according to claim 2, wherein the metal pad consists of an inner pad and an outer pad, and the width between the inner pad and the outer pad is greater than 10 μm.

5. The printed circuit board according to claim 1, wherein the surface treatment layer is a metal surface treatment layer.

6. The printed circuit board according to claim 5, wherein the metal surface treatment layer comprises at least one of Cu, Ni, Pd, Au, Sn, and Ag.

7. The printed circuit board according to claim 5, wherein the metal surface treatment layer is formed using an electroless plating method or an electroplating method.

8. The printed circuit board according to claim 7, wherein the electroless plating method comprises at least one of electroless nickel-electroless palladium-immersion gold (ENEPIG) and electroless nickel-immersion gold (ENIG).

9. The printed circuit board according to claim 1, further comprising:
a solder resist formed on the insulating layer to embed a portion of the metal pad therein.

10. A printed circuit board comprising:
an insulating layer;
a metal seed layer formed on the insulating layer;
a metal pad formed on the metal seed layer;
a surface treatment layer formed on the metal pad and the metal seed layer;
a solder layer formed on the surface treatment layer of the metal pad and the surface treatment layer of the metal seed layer; and
an intermetallic compound layer formed between the solder layer and the surface treatment layer.

11. The printed circuit board according to claim 10, wherein the plane shape of one or both of the surface treatment layer of the metal pad and the surface treatment layer of the metal seed layer on which the solder layer is formed is a ring shape.

12. The printed circuit board according to claim 11, wherein the ring-shaped surface treatment layer of the metal pad and the ring-shaped surface treatment layer of the metal seed layer are arranged alternately.

13. The printed circuit board according to claim 11, wherein the metal pad consists of an inner pad and an outer pad, and the width between the inner pad and the outer pad is greater than 10 μm.

14. The printed circuit board according to claim 10, wherein the surface treatment layer is a metal surface treatment layer.

15. The printed circuit board according to claim 14, wherein the metal surface treatment layer comprises at least one of Cu, Ni, Pd, Au, Sn, and Ag.

16. The printed circuit board according to claim 14, wherein the metal surface treatment layer is formed using an electroless plating method or an electroplating method.

17. The printed circuit board according to claim 16, wherein the electroless plating method comprises at least one of electroless nickel-electroless palladium-immersion gold (ENEPIG) and electroless nickel-immersion gold (ENIG).

18. The printed circuit board according to claim 10, further comprising:
a solder resist formed on the insulating layer to embed portions of the metal pad and the metal seed layer therein.

19. A manufacturing method of a printed circuit board comprising:
forming a metal pad on an insulating layer;
forming a surface treatment layer on the metal pad;
forming a solder layer on the surface treatment layer and the insulating layer; and
forming an intermetallic compound layer between the solder layer and the surface treatment layer.

20. The manufacturing method of a printed circuit board according to claim 19, wherein in forming the solder layer, the plane shape of one or both of the surface treatment layer and the insulating layer on which the solder layer is formed is a ring shape.

21. The manufacturing method of a printed circuit board according to claim 20, wherein the ring-shaped surface treatment layer and the ring-shaped insulating layer are arranged alternately.

22. The manufacturing method of a printed circuit board according to claim 20, wherein in forming the metal pad, the metal pad consists of an inner pad and an outer pad, and the width between the inner pad and the outer pad is greater than 10 μm.

23. The manufacturing method of a printed circuit board according to claim 19, wherein in forming the surface treatment layer, the surface treatment layer is a metal surface treatment layer.

24. The manufacturing method of a printed circuit board according to claim 23, wherein the metal surface treatment layer comprises at least one of Cu, Ni, Pd, Au, Sn, and Ag.

25. The manufacturing method of a printed circuit board according to claim 23, wherein the metal surface treatment layer is formed using an electroless plating method or an electroplating method.

26. The manufacturing method of a printed circuit board according to claim 25, wherein the electroless plating method comprises at least one of electroless nickel-electroless palladium-immersion gold (ENEPIG) and electroless nickel-immersion gold (ENIG).

27. The manufacturing method of a printed circuit board according to claim 19, further comprising, before forming the surface treatment layer, forming a solder resist on the insulating layer to embed a portion of the metal pad therein.

28. A manufacturing method of a printed circuit board comprising:
forming a metal seed layer on an insulating layer;
forming a metal pad on the metal seed layer;
forming a surface treatment layer on the metal pad and the metal seed layer;
forming a solder layer on the surface treatment layer of the metal pad and the surface treatment layer of the metal seed layer; and
forming an intermetallic compound layer between the solder layer and the surface treatment layer.

29. The manufacturing method of a printed circuit board according to claim 28, wherein in forming the solder layer, the plane shape of one or both of the surface treatment layer of the metal pad and the surface treatment layer of the metal seed layer on which the solder layer is formed is a ring shape.

30. The manufacturing method of a printed circuit board according to claim 29, wherein the ring-shaped surface treatment layer of the metal pad and the ring-shaped surface treatment layer of the metal seed layer are arranged alternately.

31. The manufacturing method of a printed circuit board according to claim 29, wherein in forming the metal pad, the metal pad consists of an inner pad and an outer pad, and the width between the inner pad and the outer pad is greater than 10 μm.

32. The manufacturing method of a printed circuit board according to claim 28, wherein in forming the surface treatment layer, the surface treatment layer is a metal surface treatment layer.

33. The manufacturing method of a printed circuit board according to claim 32, wherein the metal surface treatment layer comprises at least one of Cu, Ni, Pd, Au, Sn, and Ag.

34. The manufacturing method of a printed circuit board according to claim 32, wherein the metal surface treatment layer is formed using an electroless plating method or an electroplating method.

35. The manufacturing method of a printed circuit board according to claim 34, wherein the electroless plating method comprises at least one of electroless nickel-electroless palladium-immersion gold (ENEPIG) and electroless nickel-immersion gold (ENIG).

36. The manufacturing method of a printed circuit board according to claim 28, further comprising, before forming the surface treatment layer, forming a solder resist on the insulating layer to embed portions of the metal pad and the metal seed layer therein.
